(19) United States
(12) Patent Application Publication
(10) Pub. No.: US 2024/0136773 A1
(43) Pub. Date: Apr. 25, 2024

(54) PROTECTIVE COVER ASSEMBLY, RECEPTACLE CONNECTOR ASSEMBLY AND CONNECTOR ASSEMBLY WITH ADJUSTABLE MATING SPACE

(71) Applicant: DONGGUAN LUXSHARE TECHNOLOGIES CO., LTD, Dongguan City (CN)

(72) Inventors: Baiyu DUAN, Dongguan City (CN); Rongzhe GUO, Dongguan City (CN); Hongji CHEN, Dongguan City (CN)

(73) Assignee: DONGGUAN LUXSHARE TECHNOLOGIES CO., LTD, Dongguan City (CN)

(21) Appl. No.: 18/195,129

(22) Filed: May 8, 2023

(30) Foreign Application Priority Data
Oct. 24, 2022 (CN) 202211310165.X

(51) Int. Cl. H01R 13/6582; H01R 13/502; H01R 13/631; H01R 43/20; H05K 7/20

(52) U.S. Cl. CPC H01R 13/6582; H01R 13/502; H01R 13/631; H01R 43/20; H05K 7/20418

(57) ABSTRACT

A protective cover assembly includes a cage and an elevated cover. The cage includes a mating end surface, a first mating space and a first top wall. The first mating space extends through the mating end surface along a first direction. The first top wall includes a first opening extending along the first direction. An end of the first opening extends through the mating end surface. The elevated cover includes a first end surface and a second mating space extending through the first end surface along the first direction. The elevated cover is stacked on the cage along a second direction perpendicular to the first direction, and the first mating space communicates with the second mating space. A receptacle connector assembly and a connector assembly having the protective cover assembly are also disclosed.

### CROSS-REFERENCE TO RELATED APPLICATION

This patent application claims priority of a Chinese Patent Application No. 202211310165. X, filed on Oct. 25, 2022 and titled “PROTECTIVE COVER ASSEMBLY, RECEPTACLE CONNECTOR ASSEMBLY AND CONNECTOR ASSEMBLY”, the entire content of which is incorporated herein by reference.

### TECHNICAL FIELD

The present disclosure relates to a protective cover assembly, a receptacle connector assembly and a connector assembly, which belongs to a field of connectors.

### BACKGROUND

Generally, a connector assembly includes a receptacle connector assembly and a plug connector assembly. The receptacle connector assembly has at least one first mating space. The receptacle connector in the receptacle connector assembly is located in the first mating space. The plug connector assembly is at least partially inserted into the first mating space to be mated with the receptacle connector.

With the development of technologies, there are more and more types of plug connector assemblies. Some plug connector assemblies have heat sinks on top of it shell. It should be understood that the plug connector assembly with heat sink on the top is vertically taller than a same type of plug connector assembly without heat sink, which imposes a requirement on the height of the mating space in a corresponding receptacle connector assembly.

### SUMMARY

An object of the present disclosure is to provide a protective cover assembly, a receptacle connector assembly and a connector assembly having the protective cover assembly. The actual height of the mating space of the protective cover assembly can be adjusted, so that the receptacle connector assembly is compatible with at least two types of plug connector assemblies with different heights/thicknesses.

In order to achieve the above object, the present disclosure adopts the following technical solution: a protective cover assembly, comprising: a cage comprising a mating end surface, a first mating space and a first top wall, the first mating space extending through the mating end surface along a first direction, the first top wall comprising a first opening extending along the first direction, an end of the first opening extending to the mating end surface and extending through the mating end surface; and an elevated cover comprising a first end surface and a second mating space extending through the first end surface along the first direction; wherein the elevated cover is stacked on the cage along a second direction which is perpendicular to the first direction, and the first mating space communicates with the second mating space.

In order to achieve the above object, the present disclosure adopts the following technical solution: a receptacle connector assembly, comprising: a protective cover assembly, comprising: a cage comprising a mating end surface, a first mating space and a first top wall, the first mating space extending through the mating end surface along a first direction, the first top wall comprising a first opening extending through the mating end surface along the first direction; and an elevated cover attached to the cage, the elevated cover comprising a first end surface and a second mating space extending through the first end surface along the first direction; and a receptacle connector accommodated at a rear end of the first mating space opposite to the mating end surface; wherein the elevated cover is stacked on the cage along a second direction which is perpendicular to the first direction, and the first mating space communicates with the second mating space to jointly form an enlarged mating space; wherein the receptacle connector assembly is configured to receive a first plug connector assembly which is to be inserted into the first mating space, and a second plug connector assembly which is to be inserted into the enlarged mating space.

In order to achieve the above object, the present disclosure adopts the following technical solution: a connector assembly, comprising: a receptacle connector assembly, comprising: a protective cover assembly, comprising: a cage comprising a mating end surface, a first mating space and a first top wall, the first mating space extending through the mating end surface along a first direction, the first top wall comprising a first opening extending through the mating end surface along the first direction; and an elevated cover attached to the cage, the elevated cover comprising a first end surface and a second mating space extending through the first end surface along the first direction; and a receptacle connector accommodated at a rear end of the first mating space opposite to the mating end surface; wherein the elevated cover is stacked on the cage along a second direction which is perpendicular to the first direction, and the first mating space communicates with the second mating space to jointly form an enlarged mating space; and a plug connector assembly comprising a first plug connector assembly and/or a second plug connector assembly which is thicker than the first plug connector; wherein the receptacle connector assembly is configured to receive the first plug connector assembly which is inserted into the first mating space; and wherein the receptacle connector assembly is configured to receive the second plug connector assembly which is inserted into the enlarged mating space.

Compared with related technologies, the present disclosure has the following advantages: the first top wall of the cage of the protective cover assembly is provided with the opening, so that the actual mating space is no longer limited to the first mating space in the cage. As a result, the receptacle connector assembly having the protective cover assembly is compatible with a regular-type plug connector assembly and an elevated-type plug connector assembly.

### BRIEF DESCRIPTION OF DRAWINGS

FIG. 1 is a schematic structural view of a receptacle connector assembly in accordance with an embodiment of the present disclosure, wherein the receptacle connector assembly includes a protective cover assembly and a receptacle connector, and a sheet piece is located at a position covering an end of an elevated cover;

FIG. 2 is a schematic structural view of the receptacle connector assembly in accordance with the embodiment of the present disclosure, wherein the sheet piece is located at a certain position where it is lifted;

FIG. 3 is a partially exploded schematic view of the receptacle connector assembly in accordance with the embodiment of the present disclosure;

FIG. 4 is another partially exploded schematic view of the receptacle connector assembly from another angle;

FIG. 5 is a schematic structural view of a first top wall, a first side wall and a second side wall of the cage in accordance with an embodiment of the protective cover assembly of the present disclosure;

FIG. 6 is another schematic structural view of the first top wall, the first side wall and the second side wall of the cage from another angle;

FIG. 7 is a partially enlarged view of FIG. 6;

FIG. 8 is a structural schematic view of a first bottom wall and a heat dissipation plate of the protective cover assembly when they are assembled;

FIG. 9 is another structural schematic view of the first bottom wall and the heat dissipation plate of the protective cover assembly when they are assembled from another angle;

FIG. 10 is a partially enlarged view of FIG. 9;

FIG. 11 is a schematic view of the elevated cover and the sheet piece of the protective cover assembly in accordance with the embodiment of the present disclosure;

FIG. 12 is an exploded schematic view of the elevated cover and the sheet piece of the protective cover assembly in accordance with the embodiment of the present disclosure;

FIG. 13 is a schematic left view based on FIG. 11;

FIG. 14 is a schematic top view based on FIG. 13, wherein the elevated cover and the sheet piece are in an exploded state;

FIG. 15 is a partially enlarged view of FIG. 14;

FIG. 16 is a schematic structural view of the elevated cover of the protective cover assembly in accordance with the embodiment of the present disclosure;

FIG. 17 is a schematic structural view of a connector assembly in accordance with an embodiment of the present disclosure, wherein a regular-type plug connector assembly is inserted into the receptacle connector assembly;

FIG. 18 is an exploded schematic view of the connector assembly of FIG. 17;

FIG. 19a is a partial cross-sectional view of the connector assembly in accordance with the embodiment of the present disclosure, wherein the plug connector assembly and the receptacle connector assembly are in a mated state, and the plug connector assembly is the regular-type plug connector assembly;

FIG. 19b is a partially enlarged view of FIG. 19a;

FIG. 20 is an exploded schematic view of a connector assembly in accordance with an embodiment of the present disclosure, wherein an elevated-type plug connector assembly is separated from the receptacle connector assembly; and

FIG. 21 is a schematic structural view of the connector assembly of FIG. 20, wherein the elevated-type plug connector assembly is inserted into the receptacle connector assembly.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

In the illustrated embodiments of the present disclosure, an x-axis direction is a first direction, a y-axis direction is a second direction, and a z-axis direction is a third direction. The specific embodiments of the present disclosure will be described below with reference to the drawings.

The present disclosure discloses a protective cover assembly 100 including a cage 1.

The cage 1 includes a mating end surface 10 and a first mating space 2. The first mating space 2 extends through the mating end surface 10 along the x-axis direction. A receptacle connector 200 is accommodated at a rear end (i.e., an end that a positive direction of the x-axis points to) of the first mating space 2. A corresponding plug connector assembly 300 is configured to be at least partially inserted into the first mating space 2 to mate with the receptacle connector 200.

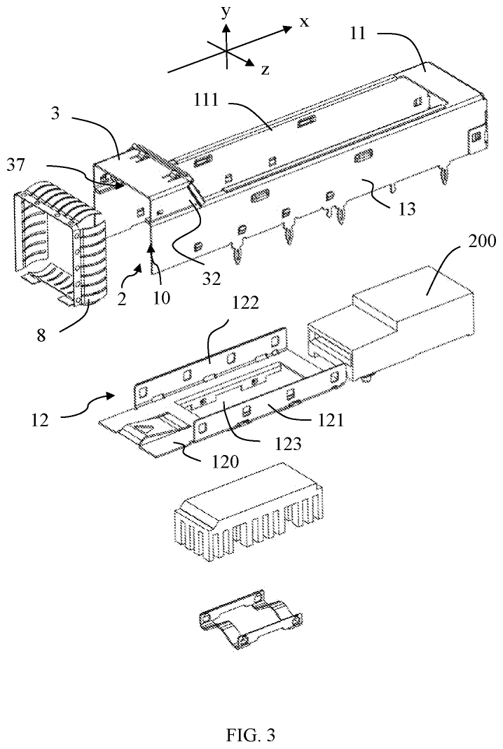

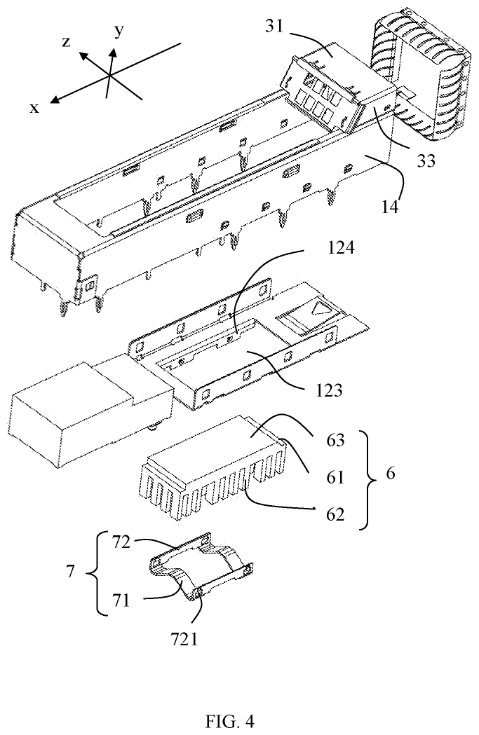

In the illustrated embodiment, referring to FIGS. 3 and 4, the cage 1 further includes a first top wall 11, a first bottom wall 12, a first side wall 13 and a second side wall 14. The first mating space 2 is at least enclosed by the first top wall 11, the second bottom wall 12, the first side wall 13 and the second side wall 14.

The first top wall 11 has a first opening 111. The first opening 111 extends along the x-axis direction. One end of the first opening 111 extends toward the mating end surface 10 and extends through the mating end surface 10; and the other end of the first opening 111 extends toward a rear end (i.e., an end that the positive direction of the x-axis points to) of the cage 1, and is at a distance from a rear end surface of the cage 1.

The first opening 111 opens the first mating space 2, so that an actual mating space is no longer limited to the first mating space 2 itself.

The actual mating space refers to a space required for the plug connector assembly 300 to move inside the protective cover assembly 100 of the receptacle connector assembly 400 when the plug connector assembly 300 is mated with the receptacle connector assembly 400. In related technologies, the actual mating space is part of the first mating space 2.

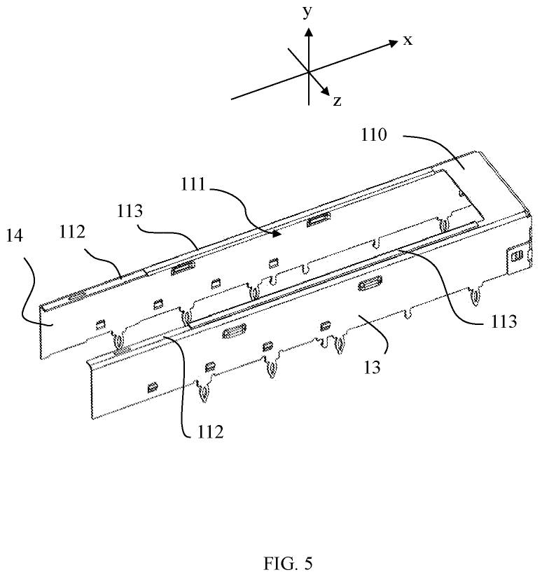

Referring to FIG. 5, the first top wall 11 includes a first wall portion 112. In the illustrated embodiment of the present disclosure, two first wall portions 112 are provided. The two first wall portions 112 are located on left and right sides (i.e., along a side that the z-axis points to) of the first opening 111, respectively. Sides of the two first wall portions 112 away from the first opening 111 are fixedly connected to the first side wall 13 and the second side wall 14, respectively.

The first top wall 11 also includes a first top wall body portion 110. Left and right sides of the first top wall body portion 110 are fixedly connected to the first side wall 13 and the second side wall 14, respectively. The first wall portion 112 extends along the x-axis direction. One end of the first wall portion 112 extends to the mating end surface 10, and the other end of the first wall portion 112 extends to the first top wall body portion 110.

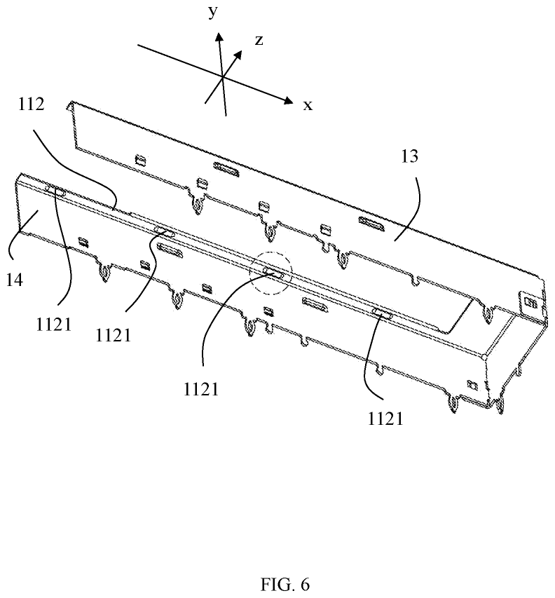

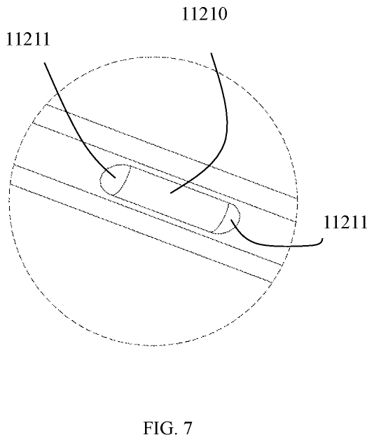

Referring to FIG. 6 and FIG. 7, the first wall portion 112 is provided with a plurality of first protrusions 1121. The plurality of first protrusions 1121 are arranged at intervals along the x-axis direction. The first protrusions 1121 protrude toward the first mating space 2 and extend along the x-axis direction.

The first protrusion 1121 has a protrusion body portion 11210 and an end portion 11211. In the illustrated embodiment of the present disclosure, two end portions 11211 are provided, which are located at front and rear ends of the protrusion body portion 11210, respectively.

In the illustrated embodiment, the protrusion body portion 11210 is a semi-cylindrical body with an approximately semicircular cross-section. An axis of the semi-cylindrical body is parallel to the x-axis. The end portion 11211 is approximately a quarter sphere. The end portion 11211 mates smoothly with the protrusion body portion 11210. That is, a diameter of the half cylindrical body is substantially equal to a diameter of the quarter sphere.

In other embodiments of the present disclosure, the protrusion body portion 11210 may also be a prism structure with a rectangular cross section. The end portion 11211 is a quarter cylindrical body with a fan-shaped cross section. Besides, the axis of the quarter cylindrical body is parallel to the z-axis direction. The end portion 11211 transitions smoothly with the protrusion body portion 11210. That is, a radius of the quarter cylindrical body constituting the end portion 11211 is equal to a protruding height of the protrusion body portion 11210 along the y-axis direction into the first mating space 2.

In other embodiments of the present disclosure, the protrusion body portion 11210 and the end portion 11211 may also be structures of other shapes. However, at least the end portion 11211 close to the mating end surface 10 has a guide surface. The guide surface smoothly extends from a lower surface of the first wall portion 112 along the positive direction of the x-axis and the negative direction of the y-axis direction to a bottom surface (i.e., a surface that the negative direction of the y-axis points to) of the protrusion body portion 11210.

In other embodiments of the present disclosure, there may be only one first protrusion 1121. In the case where only one first protrusion 1121 is provided, an extending distance of the first protrusion 1121 in the x-axis direction can be appropriately lengthened.

Referring to FIG. 5, the first top wall 11 also includes a second wall portion 113. In the illustrated embodiment of the present disclosure, two second wall portions 113 are provided, which are fixed to upper wall surfaces of the two first wall portions 112, respectively. It can be understood that fixing the second wall portion 113 to the upper wall surface of the first wall portion 112 is equivalent to increasing a thickness of the first wall portion 112, which can increase the strength of the first wall portion 112. As a result, the first wall portion 112 is not easily deformed when downward pressure is applied to the plug connector assembly 300.

The second wall portion 113 extends along the x-axis direction. One end of the second wall portion 113 extends backwardly until it is close to the first top wall body portion 110; and the other end of the second wall portion 113 extends forwardly until it is close to an elevated cover 3 mentioned below.

In other embodiments of the present disclosure, the other end of the second wall portion 113 may also extend to the mating end surface 10.

It should be understood that, viewed along the z-axis direction, a length of the second wall portion 113 is substantially the same as a length of the first wall portion 112, and the second wall portion 113 is substantially overlapped on the upper wall surface of the first wall portion 112, so as to cover as little space as possible above the first opening 111.

Referring to FIG. 3 and FIG. 4, the first bottom wall 12 includes a first bottom wall body portion 120, a first extension 121 and a second extension 122. In the illustrated embodiment, part of a left side (i.e., a side that a positive direction of the z-axis points to) of the first bottom wall body portion 120 extends toward the first top wall 11 so as to form the first extension 121. Part of a right side of the first bottom wall body portion 120 extends toward the first top wall 11 so as to form the second extension 122.

The first extension 121 and the second extension 122 are engaged with the first side wall 13 and the second side wall 14, respectively, through a snap-fit structure.

The first bottom wall 12 has a first through hole 123 which extends through the first bottom wall body portion 120 along the y-axis direction.

The first bottom wall 12 also includes a protruding wall 124. In the illustrated embodiment of the present disclosure, two protruding walls 124 are provided. The two protruding walls 124 are respectively fixedly connected to the first bottom wall body portion 120 which surrounds the first through hole 123, and is located on the left and right sides of the first through hole 123. The protruding wall 124 protrudes from the first bottom wall 12 in a direction away from the first mating space 2. In the embodiment shown in the accompanying drawings, the protruding wall 124 is obtained by extending downwardly (i.e., along the negative direction of the y-axis) from the sides of the first bottom wall body portion 120 which surrounds the first through hole 123, and is located on the left and right sides of the first through hole 123.

In other embodiments of the present disclosure, the protruding wall 124 may also be disposed on a front side and a rear side of the first through hole 123 (i.e., a side that the x-axis points to).

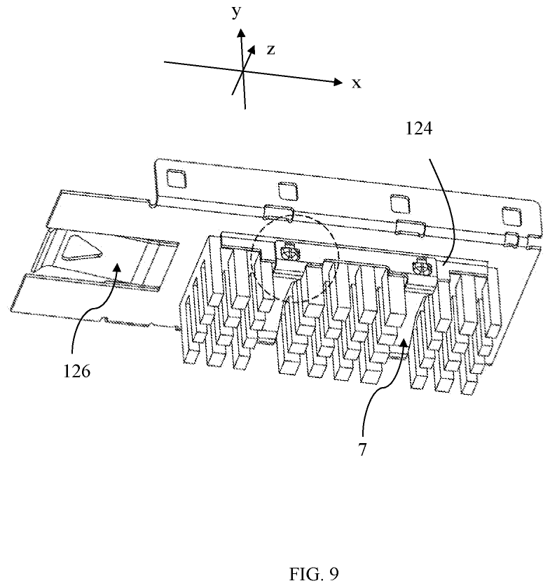

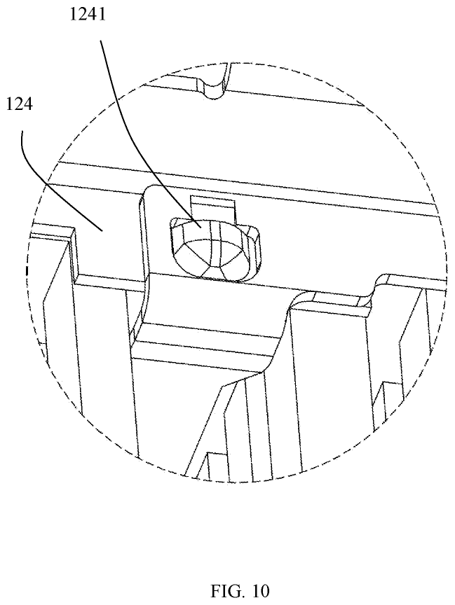

Referring to FIG. 9 and FIG. 10, two locking protrusions 1241 are arranged at intervals along the x-axis direction on the protruding wall 124.

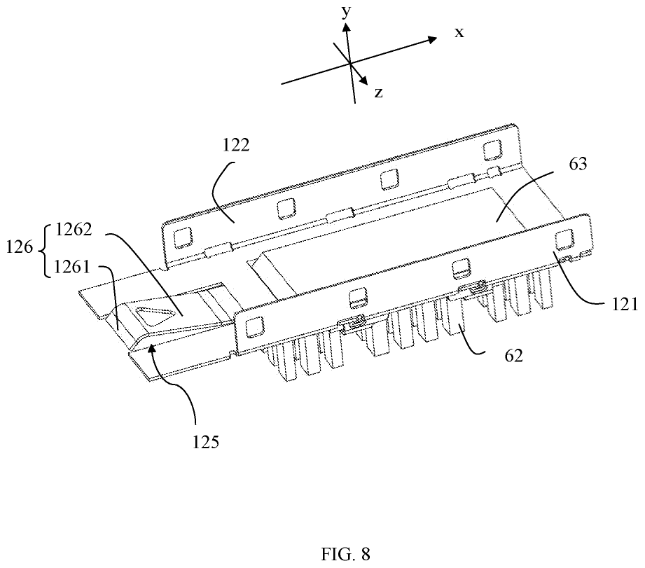

Referring to FIG. 8, the first bottom wall 12 further includes a second opening 125. The second opening 125 extends through the first bottom wall 12 along the y-axis direction. Besides, one end of the second opening 125 extends to the mating end surface 10 and extends through the mating end surface 10; and the other end of the second opening 125 extends backwardly for a certain distance along the x-axis.

Viewed along the x-axis, the second opening 125 is separated from the first through hole 123 by a certain distance.

In the embodiment shown in the drawings, the second opening 125 is located in the middle of the first bottom wall 12 when viewed along the z-axis.

The first bottom wall 12 also includes a first elastic piece 126. The first elastic piece 126 is located in the second opening 125. In the embodiment shown in the drawings, a wall surrounding the second opening 125 away from the mating end surface 10 extends into the first mating space 2 so as to form the first elastic piece 126.

The first elastic piece 126 has at least a first elastic segment 1261 and a second elastic segment 1262, wherein the first elastic segment 1261 has a guiding function. When the mating plug connector assembly 300 is inserted into the first mating space 2, the first elastic segment 1261 will guide the plug connector to lift smoothly for a certain distance.

The first elastic segment 1261 gradually extends upwardly and backwardly from a lower side of the first bottom wall 12 into the first mating space 2. The second elastic segment 1262 extends downwardly and backwardly from an inside of the first mating space 2 until it is fixedly connected with the first bottom wall body portion 120.

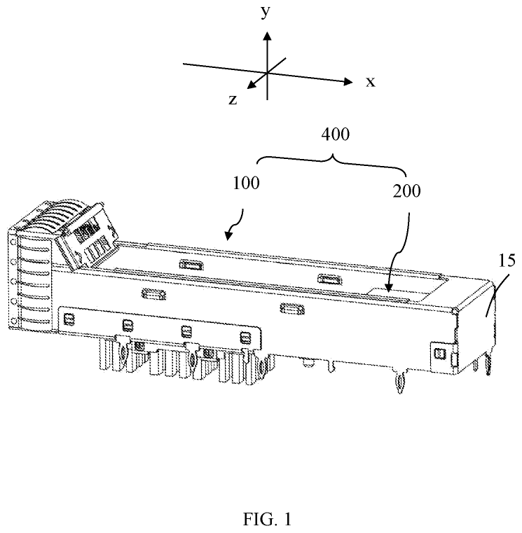

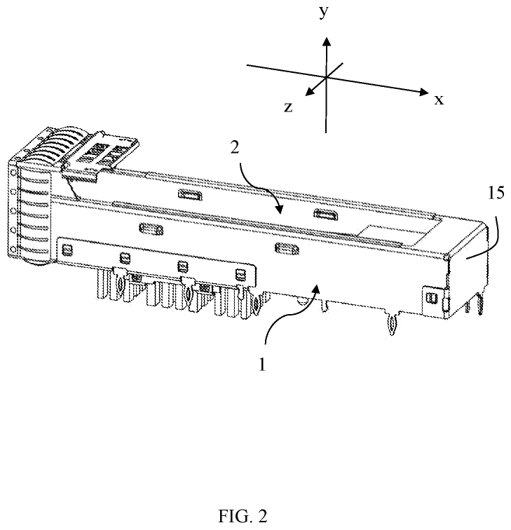

Referring to FIGS. 1 to 4, the cage 1 further includes a rear wall 15. The rear wall 15 is fixedly connected to the first top wall 11, the first side wall 13 and the second side wall 14. In the illustrated embodiment, the first top wall 11, the first side wall 13, the second side wall 14 and the rear wall 15 are integrally formed by a plate.

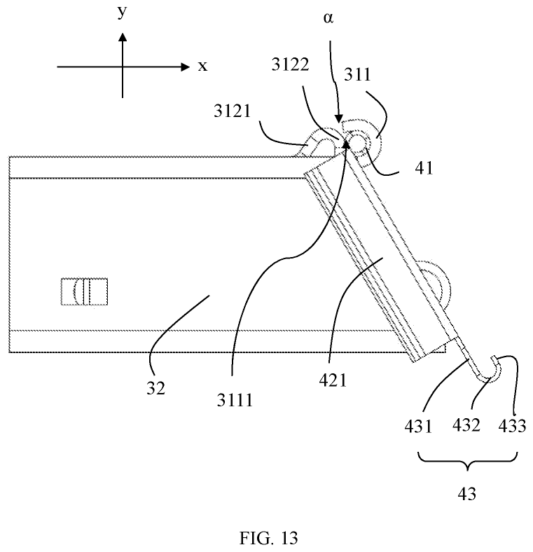

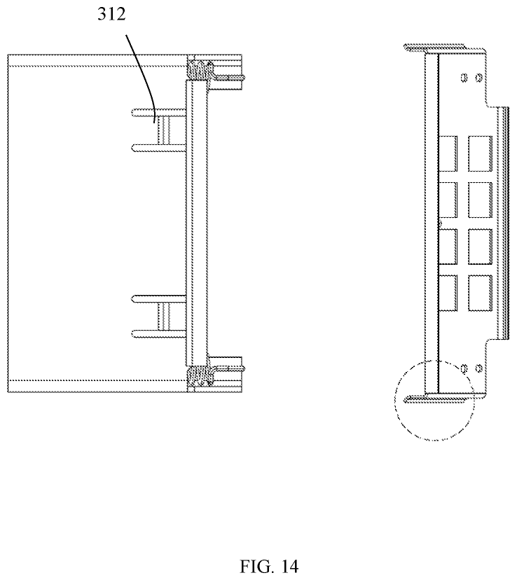

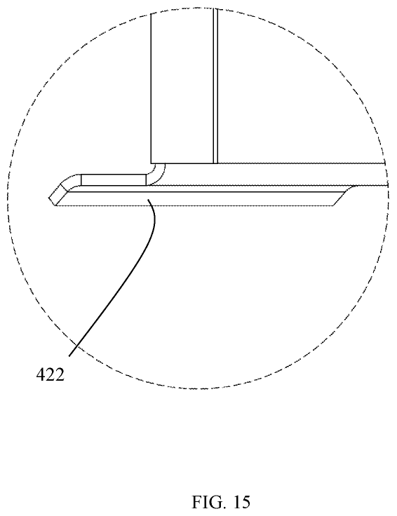

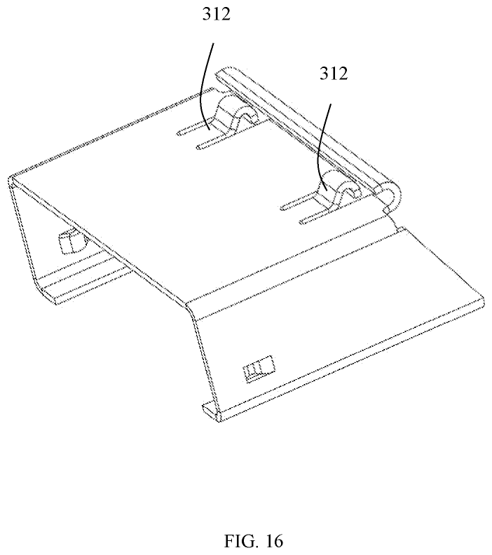

Referring to FIG. 3, FIG. 4 and FIG. 11 to FIG. 16, the protective cover assembly 100 further includes the elevated cover 3. The elevated cover 3 is fixed on an upper side of the cage 1. The elevated cover 3 includes a first end surface 34, a second end surface 35, a second mating space 37, a second top wall 31, a third side wall 32 and a fourth side wall 33.

The second mating space 37 extends through the first end surface 34 along the x-axis direction. The second top wall 31, the third side wall 32 and the fourth side wall 33 surround the outside of the second mating space 37.

The first end surface 34 is located at one end of the elevated cover 31, and the first end surface 34 is located in a same plane as the mating end surface 10. The other end of the elevated cover 31 extends for a certain distance along the x-axis direction so as to form the second end surface 35 of the elevated cover 3.

In the embodiment shown in the drawings, the second end surface 35 is inclined relative to the first top wall 11. A maximum length of the elevated cover 3 in the x-axis direction is smaller than a length of the first opening 111 in the same direction.

In the embodiment shown in the drawings, the second top wall 31 is parallel to the first top wall 11 and the first bottom wall 12. The first sidewall 13, the second sidewall 14, the third sidewall 32 and the fourth sidewall 33 are parallel. The term “parallel” means that major portions of relevant components are parallel.

The left and right sides of the second top wall 31 are fixedly connected to an upper end of the third side wall 32 and an upper end of the fourth side wall 33. A lower end of the third side wall 32 and a lower end of the fourth side wall 33 are fixedly connected to the upper end of the first side wall 13 and the upper end of the second side wall 14, respectively.

In the embodiment shown in the drawings, the second top wall 31, the third side wall 32 and the fourth side wall 33 are integrally formed by a plate.

The elevated cover 3 is stacked on the upper side of the cage 1 and covers the first opening 111 from the top. The second top wall 31, the third side wall 32, the first side wall 13, the first bottom wall 12, the second side wall 14 and the fourth side wall 33 are connected to form an enclosed configuration. It can be understood that the entire cage 1 and the elevated cover 3 are made of electromagnetic shielding material. The enclosed configuration can provide better electromagnetic shielding effect to the plug connector assembly 300 when it is located in the enclosed configuration.

In the embodiment shown in the drawings, the elevated cover 3 also has a bottom wall 36. The bottom wall 36 is spaced and parallel to the second top wall 31. In the illustrated embodiment of the present disclosure, two bottom walls 36 are provided, and are fixedly connected with the lower end of the third side wall 32 and the lower end of the fourth side wall 33, respectively.

In the embodiment shown in the drawings, one bottom wall 36 is obtained by extending a certain distance from the lower end of the third side wall 32 to the fourth side wall 33. The other bottom wall 36 is obtained by extending a certain distance from the lower end of the fourth side wall 33 facing the third side wall 32.

The two bottom walls 36 are respectively fixed to the upper surfaces of the two first wall portions 112, so that the elevated cover 3 is fixed to the first top wall 11. In the illustrated embodiment of the present disclosure, the elevated cover 3 and the cage 1 are separately made and assembled together. However, it is understandable to those of ordinary skill in the art that, in other embodiments, the elevated cover 3 and the cage 1 can be integrated formed.

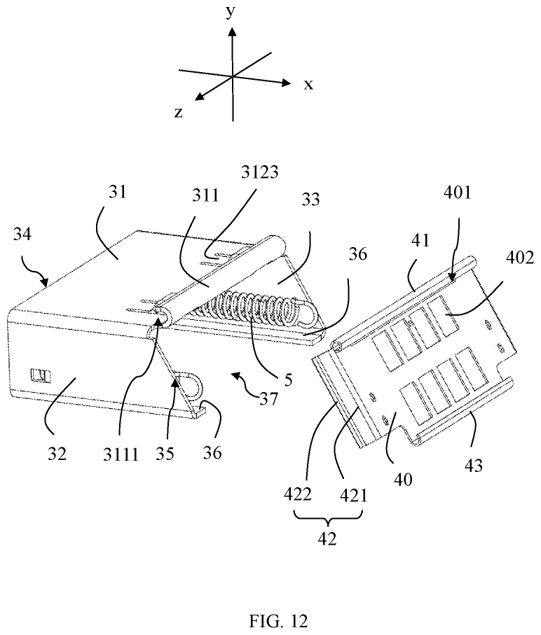

Optionally, referring to FIG. 3 and FIG. 12, along the z-axis direction, the length of the first wall portion 112 is the same as that of the bottom wall 36; and along the z-axis direction, the first wall portion 112 is aligned and fixedly connected to the bottom wall 36.

In another embodiment of the present disclosure, the elevated cover 3 may also extend to completely cover the first opening 111 in the x-axis direction.

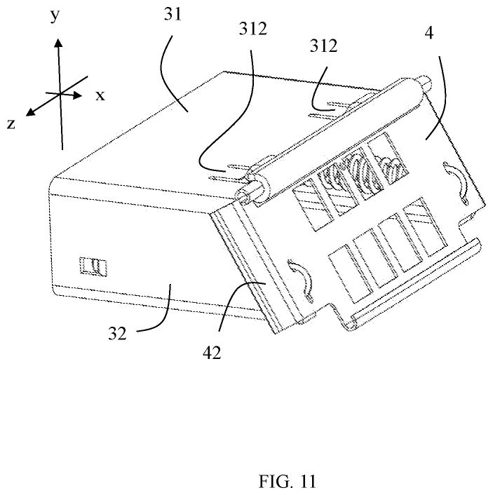

In the embodiment shown in the drawings, referring to FIGS. 11 to 16, a rear end surface of the second top wall 31 extends backwardly, upwardly and forwardly, so as to form an opening groove portion 311 with a cylindrical groove. An axis of the cylindrical groove is parallel to the z-axis direction.

The second top wall 31 further includes two raised portions 312 arranged at intervals along the z-axis direction. In the illustrated embodiment of the present disclosure, each raised portion 312 is an elastic spring integrally stamped from the second top wall 31. Each raised portion 312 has a third segment 3123, a first segment 3121 and a second segment 3122 sequentially connected along the x-axis direction. One end of the third segment 3123 is fixedly connected to a main body of the second top wall 31. The other end of the third segment 3123 is fixedly connected with one end of the first segment 3121. The other end of the first segment 3121 is fixedly connected to one end of the second segment 3122. The other end of the second segment 3122 is suspended. The third segment 3123 extends in a plane where the main body of the second top wall 31 is located. The first segment 3121 extends away from the first mating space 2 along the positive direction of the x-axis and the positive y-axis direction. The second segment 3122 extends along the positive direction of the x-axis and the negative direction of the y-axis in a direction close to the first mating space 2. The second segment 3122 corresponds to the opening 3111 of the opening groove portion 311, and partially blocks the opening of the opening groove portion 311. There is a certain gap α between the second segment 3122 and a groove wall at the opening of the opening groove portion 311.

Referring to FIG. 11 to FIG. 15, the protective cover assembly 100 further includes a sheet piece 4. The sheet piece 4 covers the rear end of the elevated cover 3. In the embodiment shown in the drawings, one end of the sheet piece 4 is rotatably connected to the rear end of the second top wall 31.

Specifically, the sheet piece 4 has a rotating shaft 41, a sheet body portion 40, two side wings 42 and a tail 43. An upper end of the sheet body portion 40 is fixed to the rotating shaft 41. The rotating shaft 41 can be snapped into the groove of the opening groove portion 311 from the gap α between the raised portion 312 and the groove wall of the opening groove portion 311. The second segment 3122 of the raised portion 312 prevents the rotating shaft 41 from moving out of the groove of the opening groove portion 311 along the negative direction of the x-axis.

It should be understood that in order to enable the sheet piece 4 to rotate relative to the opening groove portion 311 without interfering with the groove wall of the opening groove portion 311, an escape opening 401 is formed at an end of the sheet body portion 40 close to the rotating shaft 41. The left end and the right end of the upper side of the sheet body portion 40 are fixedly connected with the rotating shaft 41.

The sheet piece 4 further includes two side wings 42 which are located on the left and right sides of the sheet piece main body 40, respectively. The side wing 42 includes a covering portion 421 and a guiding portion 422. When the sheet piece 4 covers the rear end of the elevated cover 3, the covering portion 421 at least partially covers an outside of the third side wall 32 or an outside of the fourth side wall 33.

In the embodiment of the drawings, the left and right side edges of the sheet body portion 40 extend a certain distance toward the elevated cover 3 in a direction perpendicular to the sheet body portion 40 so as to form the covering portion 421. The side of the covering portion 421 away from the sheet body portion 40 is tilted in a direction away from the elevated cover 3 along a direction perpendicular to the third side wall 32 or the fourth side wall 33 so as to form the guiding portion 422.

Part of the end surface of the rear end of the sheet body portion 40 extends in a direction away from the sheet body portion 40 in a plane where the sheet body portion 40 is located. After turning over 180°, part of the end surface of the rear end of the sheet body portion 40 continues to extend for a certain distance in a direction parallel to the sheet body portion 40 so as to form the tail 43.

In the illustrated embodiment, the tail 43 includes three portions: a first portion 431, a second portion 432 and a third portion 433.

The first portion 431 is a flat plate extending in the plane of the sheet body portion 40. The second portion 432 is an arc plate in a shape of a semi-cylindrical side wall. The third portion 433 is a flat plate extending in a plane parallel to the sheet body portion 40. The second portion 432 connects the first portion 431 and the third portion 433.

In another embodiment of the present disclosure, the tail 43 is an arc-shaped surface raised upwardly and backwardly from the sheet piece main body portion 40.

When the sheet piece 4 covers the rear end of the elevated cover 3, the tail 43 protrudes into the first mating space 2.

Optionally, a plurality of through slots 402 are provided on the sheet body portion 40.

The protective cover assembly 100 also includes an elastic member. The elastic member is arranged between the sheet piece 4 and the elevated cover 3. The elastic element provides a force to the sheet element 4 against the second end surface 35 of the elevated cover 3.

In the illustrated embodiment, the elastic member is a spring 5. In the illustrated embodiment of the present disclosure, two springs 5 are provided and arranged in the protective cover assembly 100. Each of the two springs 5 is located inside the elevated cover 3 as a whole. The spring 5 extends along a side wall of the closed cover 3 adjacent thereto, so as to allow a space between the third side wall 32 and the fourth side wall 33 as much as possible. Referring to FIG. 11 and FIG. 12, a first one of the two springs 5 extends along the third side wall 32. One end of the first one of the two springs 5 is hooked to the third side wall 32, and the other end of the first one of the two springs 5 is hooked to the sheet body portion 40. A second one of the two springs 5 extends along the fourth side wall 33. One end of the second one of the two springs 5 is hooked to the fourth side wall 33, and the other end of the second one of the two springs 5 is hooked to the sheet body portion 40.

It should be understood that other elastic structures such as a torsion spring may also be selected for the elastic member.

In the previous embodiments, the sheet piece 4 is connected in rotation to the elevated cover 3. In other embodiments of the present disclosure, the sheet piece 4 can also be fixedly connected to the elevated cover 3. At this time, relying on its own strong elasticity, the sheet piece 4 can be lifted up a certain distance in the y-axis direction, so that the protective cover assembly 100 is compatible with the regular-type plug connector assembly 300′ and the elevated-type plug connector assembly 300″.

The protective cover assembly 100 also includes a heat dissipation plate 6. Referring to FIG. 4, the heat dissipation plate 6 is fixed to the first bottom wall 12. The heat dissipation plate 6 partially protrudes into the first mating space 2 through the first through hole 123.

The heat dissipation plate 6 includes a heat dissipation substrate 61 and a plurality of heat dissipation fins 62. The plurality of heat dissipation fins 62 are arrayed and fixed on a lower surface of the heat dissipation substrate 61.

The heat dissipation plate 6 also has a protrusion 63. The protrusion 63 protrudes upwardly from an upper surface of the heat dissipation substrate 61. The protrusion 63 extends along the x-axis direction. One end of the protrusion 63 extends to a certain distance from a front end of the heat dissipation substrate 61, and the other end of the protrusion 63 extends to a certain distance from a rear end of the heat dissipation substrate 61.

A front end surface of the protrusion 63 is inclined relative to the upper surface of the heat dissipation substrate 61.

The protective cover assembly 100 also includes a locking member 7. In the illustrated embodiment of the present disclosure, the locking member 7 has two first connecting bars 71 spaced and juxtaposed along the x-axis direction, and two second connecting bars 72 spaced and juxtaposed along the z-axis direction. The two second connecting bars 72 are fixed to two ends of the two first connecting bars 71, respectively.

The second connecting bar 72 has two positioning holes 721. The two positioning holes 721 are arranged at intervals along the x-axis direction.

The two first connecting bars 71 can pass between the heat dissipation fins 62 of the array. The positioning holes 721 is locked with the locking protrusions 1241, so that the heat dissipation plate 6 is fixed on the first bottom wall 12.

After the heat dissipation plate 6 is fixed on the first bottom wall 12, the upper surface of the heat dissipation substrate 61 abuts against the lower surface of the first bottom wall 12, and the protrusion 63 protrudes into the first mating space 2.

The protective cover assembly 100 also includes a ground elastic piece 8. The ground elastic piece 8 is fixedly connected to an outer surface of an enclosed configuration which is enclosed by the second top wall 31, the fourth side wall 33, the second side wall 14, the first bottom wall 12, the second side wall 13 and the third side wall 32.

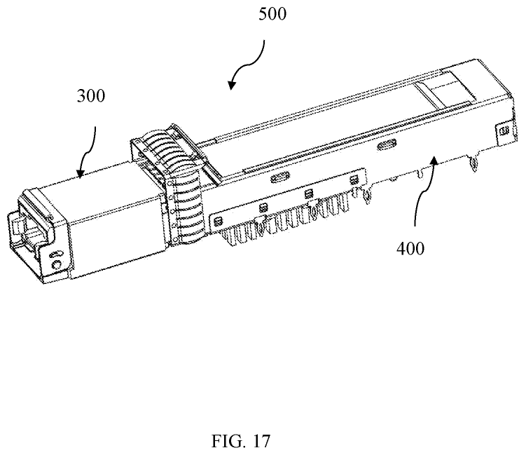

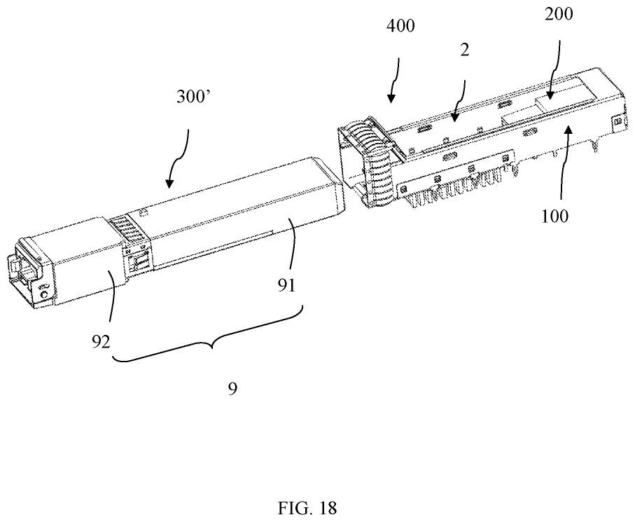

The present disclosure also discloses a receptacle connector assembly 400. As shown in FIG. 1, FIG. 17 and FIG. 18, the receptacle connector assembly 400 includes the protective cover assembly 100 described above, and the receptacle connector 200. The receptacle connector 200 is accommodated at the rear end of the first mating space 2.

The present disclosure also discloses a connector assembly 500, as shown in FIG. 17, which includes the plug connector assembly 300 and the receptacle connector assembly 400 disclosed above.

The plug connector assembly 300 includes a shell 9 and a plug connector (not labeled) accommodated in the shell 9. The shell 9 includes a first shell portion 91 and a second shell portion 92. In the present disclosure, the first shell portion 91 is also referred to as an insertion portion.

As can be seen from the foregoing, the receptacle connector assembly 400 in the present disclosure is compatible with the regular-type plug connector assembly 300′ and the elevated-type plug connector assembly 300″.

The term “regular-type” used in the regular-type plug connector assembly 300′ in the present disclosure refers to a plug connector assembly that is relatively short or does not have a heat dissipation fin installed.

That is, the regular-type plug connector assembly 300′ in the present disclosure is a shorter plug connector assembly 300 than an elevated plug connector assembly 300″. It can also be expressed as, the elevated-type plug connector assembly 300″ in the present disclosure is a higher plug connector assembly than the regular-type general plug connector assembly 300′ that matches the receptacle connector assembly 400. More specifically, in the present disclosure, the regular-type plug connector assembly 300′ refers to the plug connector assembly 300 that is not equipped with a receptacle heat sink 93 mentioned below compared with the elevated plug connector assembly 300″.

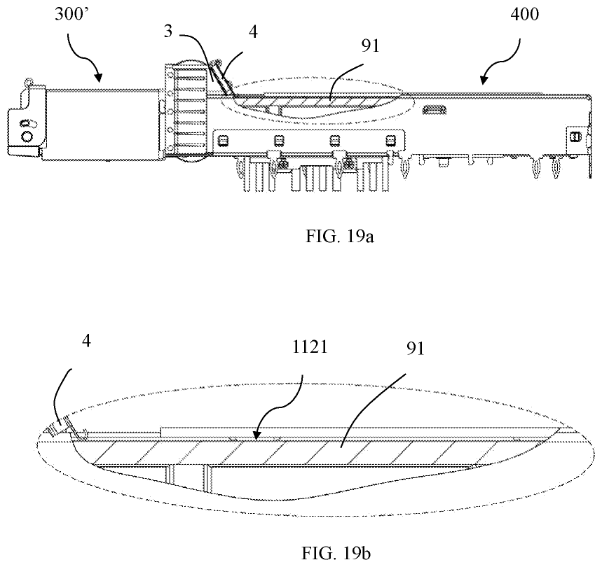

Referring mainly to FIGS. 17 to 19b, the first shell portion 91 is inserted into the first mating space 2 of the protective cover assembly 100 when mated with the regular-type plug connector assembly 300′. The plug connector located in the shell 9 is electrically connected to the receptacle connector 200 located at the rear end of the first mating space 2.

The sheet piece 4 covers and presses the second end surface 35 of the elevated cover 3 under the tension of the spring 8. Moreover, the tail 43 of the sheet piece 4 presses against the upper surface of the insertion portion, giving a downward force to an upper surface of the insertion portion. The upper surface of the insertion portion of the plug connector assembly 300′ abuts against the first protrusion 1121.

Both the tail 43 and the first protrusion 1121 give the plug connector assembly 300′ a downward force. The insertion portion is closely contacted with the protrusion 63 of the heat dissipation plate 6 on the lower side of the insertion portion, so that the heat dissipation performance of the heat dissipation plate 6 is better.

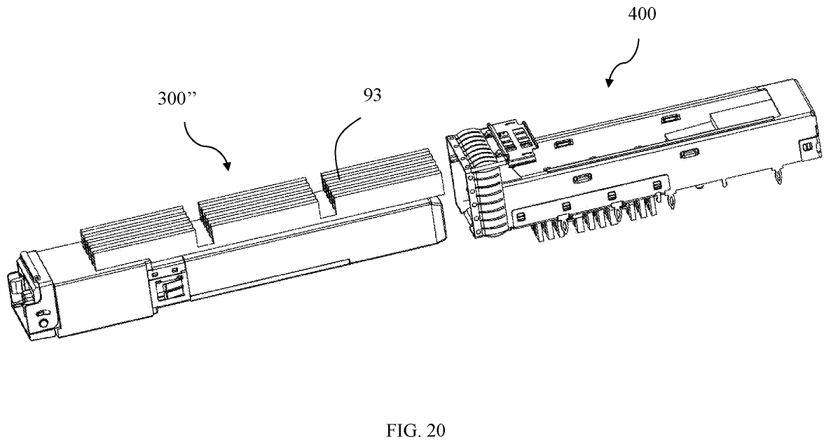

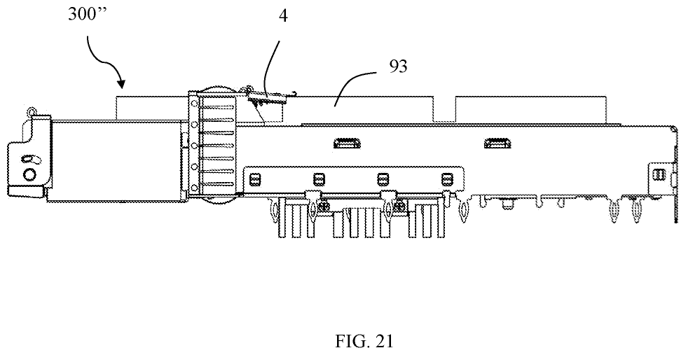

Referring to FIG. 20, compared with the regular-type plug connector assembly 300′ described above, the elevated-type plug connector assembly 300″ further includes a receptacle heat sink 93. The receptacle heat sink 93 is fixed on the upper surface of the shell 9.

When the elevated-type plug connector assembly 300″ is mated with the receptacle connector assembly 400, the insertion portion is inserted into the first mating space 2 in the protective cover assembly 100. At the same time, the receptacle heat sink 93 located on the upper surface of the shell 9 passes through the second mating space 37, lift up the sheet piece 4, and is at least partially exposed to the air above the first opening 111.

The tail 43 of the sheet piece 4 presses against the upper surface of the insertion portion under the tension of the spring 8. The first protrusion 1121 abuts against the upper surface of the insertion portion of the plug connector assembly 300″. Both the tail 43 and the first protrusion 1121 provide a downward force on the insertion portion, so that the lower surface of the insertion portion is in close contact with the protrusion 63. As a result, the heat dissipation effect of the heat dissipation plate 6 is better.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A protective cover assembly configured to shied an electrical connector, comprising:
a cage comprising a mating end surface, a first mating space and a first top wall, the first mating space extending through the mating end surface along a first direction, the first top wall comprising a first opening extending along the first direction, an end of the first opening extending to the mating end surface and extending through the mating end surface; and
an elevated cover comprising a first end surface and a second mating space extending through the first end surface along the first direction;
wherein the elevated cover is stacked on the cage along a second direction which is perpendicular to the first direction, and the first mating space communicates with the second mating space.

2. The protective cover assembly according to claim 1, wherein the cage comprises a first bottom wall, a first side wall and a second side wall; and the first mating space is at least formed by the first top wall, the first bottom wall, the first side wall and the second side wall.

3. The protective cover assembly according to claim 2, wherein the first top wall further comprises two first wall portions;
wherein viewed along a third direction, the two first wall portions are located on opposite sides of the first opening, respectively; sides of the two first wall portions away from the first opening are fixedly connected to the first side wall and the second side wall, respectively; and
wherein the third direction is perpendicular to the first direction and the second direction.

4. The protective cover assembly according to claim 3, wherein a first protrusion is provided on a wall surface of the first wall portion facing the first mating space; or
a plurality of first protrusions are provided on the wall surface of the first wall portion facing the first mating space; and the plurality of first protrusions are arranged at intervals along the first direction.

5. The protective cover assembly according to claim 4, wherein viewed along the first direction, the first protrusion has a protrusion body portion and an end portion;
the end portion close to the mating end surface has a guide surface, the guide surface smoothly extends from the wall surface of the first wall portion to a bottom surface of the protrusion body portion along the first direction and the second direction;
the bottom surface of the protrusion body portion is a surface of the protrusion body portion away from the first wall portion.

6. The protective cover assembly according to claim 3, wherein the first top wall further has a second wall portion;
wherein the second wall portion at least partially covers and is fixed to an upper wall surface of the first wall portion; and
wherein the upper wall surface of the first wall portion is a wall surface of the first wall portion away from the first mating space along the second direction.

7. The protective cover assembly according to claim 3, wherein the elevated cover comprises two bottom walls which are parallel to the first wall portion; and the two bottom walls are fixed to the two first wall portions, respectively.

8. The protective cover assembly according to claim 2, wherein the first bottom wall has a first through hole which extend through the first bottom wall along the second direction;
the protective cover assembly further comprises a heat dissipation plate which is fixed to the first bottom wall; and the heat dissipation plate partially protrudes into the first mating space through the first through hole.

9. The protective cover assembly according to claim 2, wherein the elevated cover further comprises a second top wall, a third side wall and a fourth side wall; the second mating space is at least formed by the second top wall, the third side wall and the fourth side wall; and the third side wall and the fourth side wall are fixedly connected to the first side wall and the second side wall, respectively.

10. The protective cover assembly according to claim 9, wherein the elevated cover extends along the first direction;
wherein the first end surface is located at one end of the elevated cover, the first end surface is located on a same plane as the mating end surface, and another end of the elevated cover is at a certain distance from the first end surface; and
wherein in the first direction, a maximum length of the elevated cover is smaller than a length of the first opening.

11. The protective cover assembly according to claim 10, wherein an end surface of the another end of the elevated cover is inclined relative to the first top wall.

12. The protective cover assembly according to claim 10, further comprising a sheet piece, the sheet piece at least partially covers an end surface of the another end of the elevated cover, and the another end of the sheet piece is configured to be movable a certain distance along the second direction.

13. The protective cover assembly according to claim 12, wherein one end of the sheet piece is connected to the second top wall, and another end of the sheet piece extends into the first mating space;
wherein the one end of the sheet piece is rotatably connected to the second top wall; and
wherein the protective cover assembly further comprises an elastic member disposed between the sheet piece and the elevated cover, and the elastic member gives the sheet piece a force against the another end of the elevated cover.

14. The protective cover assembly according to claim 13, wherein the protective cover assembly comprises two elastic members, and an entirety of each of the elastic members is located inside the elevated cover;
one of the two elastic members extends along the third side wall, and one end of the one of the two elastic members is connected to the third side wall, and another end of the one of the two elastic members is connected to the sheet piece;
a remaining one of the two elastic members extends along the fourth side wall, and one end of the remaining one of the two elastic members is connected to the fourth side wall, and another end of the remaining one of the two elastic members is connected to the sheet piece.

15. The protective cover assembly according to claim 13, wherein the second top wall comprises an opening groove portion; the opening groove portion is located at the another end of the elevated cover; the opening groove portion comprises a cylindrical groove; and the sheet piece has a rotating shaft rotatably accommodated in the cylindrical groove; and
wherein the second top wall has a raised portion; the raised portion partially blocks an opening of the opening groove portion; a gap is formed between the raised portion and a groove wall at the opening of the opening groove portion.

16. The protective cover assembly according to claim 13, wherein the sheet piece has a sheet body portion, a rotating shaft and a tail;
the rotating shaft is located at the one end of the sheet piece, and the sheet piece is rotatably connected to the second top wall through the rotating shaft;
the tail is located at the another end of the sheet piece;
the sheet body portion is connected to the rotating shaft and the tail;
the tail tilts up from the sheet body portion in a direction away from the sheet body portion and away from the first mating space.

17. A receptacle connector assembly, comprising:
a protective cover assembly, comprising:
a cage comprising a mating end surface, a first mating space and a first top wall, the first mating space extending through the mating end surface along a first direction, the first top wall comprising a first opening extending through the mating end surface along the first direction; and
an elevated cover attached to the cage, the elevated cover comprising a first end surface and a second mating space extending through the first end surface along the first direction; and
a receptacle connector accommodated at a rear end of the first mating space opposite to the mating end surface;
wherein the elevated cover is stacked on the cage along a second direction which is perpendicular to the first direction, and the first mating space communicates with the second mating space to jointly form an enlarged mating space;
wherein the receptacle connector assembly is configured to receive a first plug connector assembly which is to be inserted into the first mating space, and a second plug connector assembly which is to be inserted into the enlarged mating space.

18. The receptacle connector assembly according to claim 17, wherein the elevated cover comprises a second end surface opposite to the first end surface;
wherein the cage further comprises a sheet piece at least partially covering the second end surface, and the sheet piece is rotatably connected to the elevated cover; and
wherein the sheet piece is lifted up by the second plug connector assembly so that a pressing force is generated for the sheet piece to press against the second plug connector assembly.

19. The receptacle connector assembly according to claim 18, wherein the protective cover assembly further comprises an elastic member disposed between the sheet piece and the elevated cover, and the pressing force is generated by the elastic member.

20. A connector assembly, comprising:
a receptacle connector assembly, comprising:
a protective cover assembly, comprising:
a cage comprising a mating end surface, a first mating space and a first top wall, the first mating space extending through the mating end surface along a first direction, the first top wall comprising a first opening extending through the mating end surface along the first direction; and
an elevated cover attached to the cage, the elevated cover comprising a first end surface and a second mating space extending through the first end surface along the first direction; and
a receptacle connector accommodated at a rear end of the first mating space opposite to the mating end surface;
wherein the elevated cover is stacked on the cage along a second direction which is perpendicular to the first direction, and the first mating space communicates with the second mating space to jointly form an enlarged mating space; and
a plug connector assembly comprising a first plug connector assembly and/or a second plug connector assembly which is thicker than the first plug connector;
wherein the receptacle connector assembly is configured to receive the first plug connector assembly which is inserted into the first mating space; and
wherein the receptacle connector assembly is configured to receive the second plug connector assembly which is inserted into the enlarged mating space.
